(19) United States
(12) Patent Application Publication
(10) Pub. No.: US 2020/0166566 A1
(43) Pub. Date: May 28, 2020

(54) INTRALAYER CONDUCTIVE DEFECT DETECTION STRUCTURE

(71) Applicant: QUALCOMM Incorporated, San Diego, CA (US)

(72) Inventors: Samit SENGUPTA, San Diego, CA (US); Fadoua CHAFIK, San Diego, CA (US)

(21) Appl. No.: 16/203,042

(22) Filed: Nov. 28, 2018

(51) Int. Cl. G01R 31/28; G01R 31/3185

(52) U.S. Cl. CPC G01R 31/2856; G01R 31/2831; G01R 31/318511; G01R 31/2884; G01R 31/2812; G01R 31/2836

(57) ABSTRACT

An integrated circuit test structure has a first set of unit cells in a first conductive layer. The first set of unit cells has a first portion to receive a charge of a first polarity and a second portion to receive a charge of a second polarity. The first portion is electrically independent of the second portion. The first portion has branched conductive lines interdigitated with branched conductive lines of the second portion. The integrated circuit test structure also has a second set of unit cells in the first conductive layer. The second set of unit cells are transposed relative to the first set of unit cells.

### BACKGROUND

### Field

Aspects of the present disclosure relate to integrated circuit fabrication and, more particularly, to a test structure fabricated on an integrated circuit structure to improve yield in semiconductor manufacturing processes.

### Background

As integrated circuit (IC) technology advances, device (e.g., semiconductor device) geometries are reduced. Reducing the geometry and “pitch” (e.g., spacing) between integrated circuit devices may cause the integrated circuit devices to interfere with each other and affect proper operation.

These integrated circuit devices may include different types of transistors. For example, the devices may include planar transistors, fin-based transistors or gate-all-around (GAA) transistors. Fin-based transistors are three-dimensional structures on the surface of a semiconductor substrate. A fin-based transistor, which may be a fin-based metal-oxide-semiconductor field-effect transistor (MOSFET), may be referred to as a FinFET. A nanowire field-effect transistor (FET) is also a three-dimensional structure on the surface of a semiconductor substrate. A nanowire FET includes doped portions of the nanowire that contact a channel region and serve as the source and drain regions of the device. A nanowire FET is also an example of a MOSFET device.

Fabrication of semiconductor integrated circuits specifies that precisely controlled quantities of impurities be introduced into small regions of a semiconductive substrate and that these regions be interconnected to create microelectronic components and integrated circuits. As a result, the manufacture of semiconductor integrated circuits involves a loss of chip yield due to the presence of various defects. An example of a defect that may occur when conductive layers are formed on an integrated circuit is extra material defects. Extra material defects may occur when the conductive structures include material extending beyond predefined boundaries. Such material may extend to another conductive structure, causing a short to be formed between the two conductive structures.

### SUMMARY

An integrated circuit test structure has a first set of unit cells in a first conductive layer. The first set of unit cells has a first portion to receive a charge of a first polarity and a second portion to receive a charge of a second polarity. The first portion is electrically independent of the second portion. The first portion has branched conductive lines interdigitated with branched conductive lines of the second portion. The integrated circuit test structure also has a second set of unit cells in the first conductive layer. The second set of unit cells is transposed relative to the first set of unit cells.

A method of fabricating an integrated circuit test structure includes fabricating a first set of unit cells in a first conductive layer. The first set of unit cells has a first portion to receive a charge of a first polarity and a second portion to receive a charge of a second polarity. The first portion is electrically independent of the second portion. The first portion has branched conductive lines interdigitated with branched conductive lines of the second portion. The method of fabricating the integrated circuit test structure also includes fabricating a second set of unit cells in the first conductive layer. The second set of unit cells is transposed relative to the first plurality of unit cells.

An integrated circuit test structure has a first set of unit cells in a first conductive layer. The first set of unit cells has a first portion to receive a charge of a first polarity and a second portion to receive a charge of a second polarity. The first portion is electrically independent of the second portion. The first portion has branched conductive lines interdigitated with branched conductive lines of the second portion. The integrated circuit test structure also includes means for detecting latent defect in the first conductive layer. The latent defect detecting means are transposed relative to the first plurality of unit cells.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of a die.

FIG. 3 illustrates a cross-sectional view of a metal-oxide-semiconductor field-effect transistor (MOSFET) device.

FIG. 4 illustrates a fin field-effect transistor (FinFET).

FIG. 5 illustrates a test structure having a double comb structure.

FIG. 6 illustrates a dendritic integrated circuit test structure, according to aspects of the present disclosure.

FIG. 7 illustrates a dendritic integrated circuit test structure, according to aspects of the present disclosure.

FIG. 8 illustrates a method for fabricating an integrated circuit test structure, according to aspects of the present disclosure.

FIG. 9 is a block diagram showing an exemplary wireless communication system in which an integrated circuit test structure of the disclosure may be advantageously employed.

FIG. 10 is a block diagram illustrating a design workstation used for circuit, layout, and logic design of an integrated circuit test structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably.

Fabrication processes (e.g., complementary metal-oxide-semiconductor (CMOS) fabrication processes) are often divided into three parts: a front-end-of-line (FEOL), a middle-of-line (MOL), and a back-end-of-line (BEOL). Front-end-of-line processes include wafer preparation, isolation, well formation, gate patterning, spacers, and dopant implantation. A middle-of-line process includes gate and terminal contact formation. Back-end-of-line processes include forming interconnects and dielectric layers for coupling to the FEOL devices.

As technology scaling continues, associated shrinking of integrated circuit device elements creates latent defects that arise during fabrication of the integrated circuits. For example, shrinking of a gate pitch reduces the spacer area between the source/drain trench (CA) contacts and the gate stack. This causes a dramatic increase in the latent defects. Latent defects are defects that are not detectable at fabrication screening or at time-zero (T0) screening (wafer or die probe) but causes failure either at burn-in (very expensive screen test) or in the field and causes the integrated circuit device to be returned in accordance with return merchandise authorizations (RMAs).

The latent defects significantly affect logic and radio frequency (RF) circuit functionality or performance because these defects may cause bridging or shorts across adjacent metal levels. Because such defects (e.g., latent bridging defects) are marginal and can cause circuit failure over time, it is especially important for automotive applications that such defects be minimized or reduced at the source (e.g., silicon chip processing stage or initial electrical testing stage), prior to shipping to customers or prior to expensive screening or potential RMAs.

Chip designs for automotive applications are specified to pass stringent reliability criteria to meet one defect part per million (DPPM), which specifies extensive and expensive screenings of latent defects post-fabrication (e.g., sophisticated screening at wafer probe, burn-in stress and system-level testing, and extensive automatic test equipment (ATE) testing). These tests can be at a wafer and package level, across different temperature, voltage, and ambient conditions. Other tests or outlier screening methodology include dynamic part averaging testing (DPAT) and good die in bad neighborhood (GDBN) screening. Such screenings or controls, however, do not catch all existing latent defects. Accordingly, shipped units are exposed to potential on-field failure. To further minimize or reduce return merchandise authorizations (RMAs) to near-zero levels, process innovations are desirable to reduce the incidence of latent defects such as interconnect bridging.

Aspects of the present disclosure are directed to an integrated circuit test structure (e.g., a conductive interconnect test structure) that addresses known shortcomings with current technology. The conductive interconnect test structure detects and prevents latent defects (e.g., intra-layer metal-to-metal bridging, minor chemical mechanical planarization (CMP) scratches, etc.) that exist on chip or integrated circuit devices within conductive layers (e.g., BEOL layers). The interconnect test structure exposes latent defects/faults at wafer/die probe, by covering large areas on a chip (or adjacent process control monitor (PCM) modules) of metal layer(s) of interest.

In one aspect, the test structure of an integrated circuit includes a first contact pad of a first polarity in a first conductive (e.g., metal) layer and a second contact pad of a second polarity in the first conductive layer. The integrated circuit test structure further includes a first set of unit cells in the first conductive layer. The first set of unit cells include a first portion of the first polarity and a second portion of the second polarity. The first portion is coupled to the first contact pad. The first portion includes branched conductive lines interdigitated with branched conductive lines of the second portion. The second portion is coupled to the second contact pad. A second set of unit cells in the first conductive layer is transposed (e.g., rotated/mirrored) relative to the first set of unit cells.

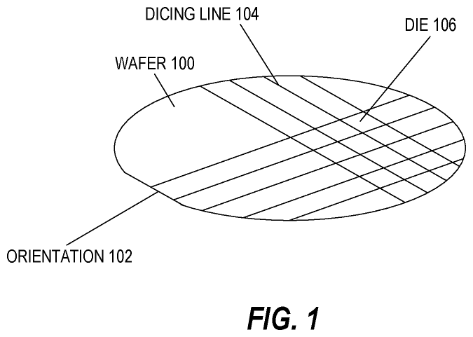

FIG. 1 illustrates a perspective view of a semiconductor wafer. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller indices for the planes of the crystal lattice in the wafer 100.

The Miller indices form a notation system of the crystallographic planes in crystal lattices. The lattice planes may be indicated by three integers h, k, and

[symbol]

, which are the Miller indices for a plane (hk [symbol] )
in the crystal. Each index denotes a plane orthogonal to a direction (h, k, [symbol] )
in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to [symbol] .
For some crystals, negative numbers are used (written as a bar over the index number) and for some crystals, such as gallium nitride, more than three numbers may be employed to adequately describe the different crystallographic planes.

Once the wafer 100 has been processed as desired and tested, the wafer 100 is divided up along dicing lines 104. The dicing lines 104 indicate where the wafer 100 is to be broken apart or separated into pieces. The dicing lines 104 cut through the wafer scribeline region, which may include the circuit test-structure (in the PCM), which is tested prior to dicing. The dicing lines 104 may define the outline of the various integrated circuits that have been fabricated on the wafer 100. The fabricated integrated circuits may also include the integrated circuit test structure. As a result, failure detection in the integrated circuit test-structure due to metal-metal shorts induced by latent defects is accelerated.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

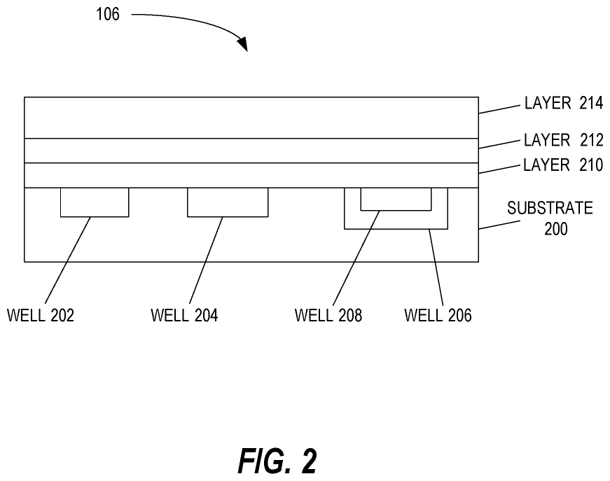

FIG. 2 illustrates a cross-sectional view of a die 106. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204 of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

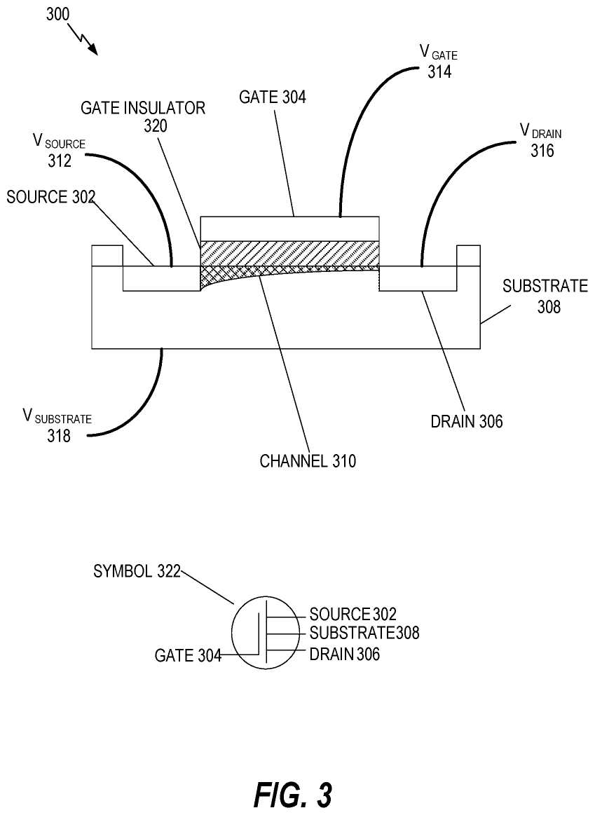

FIG. 3 illustrates a cross-sectional view of a metal-oxide-semiconductor field-effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in a channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. A gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon”, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers (e.g., 210-214), or may be in other layers of the die 106.

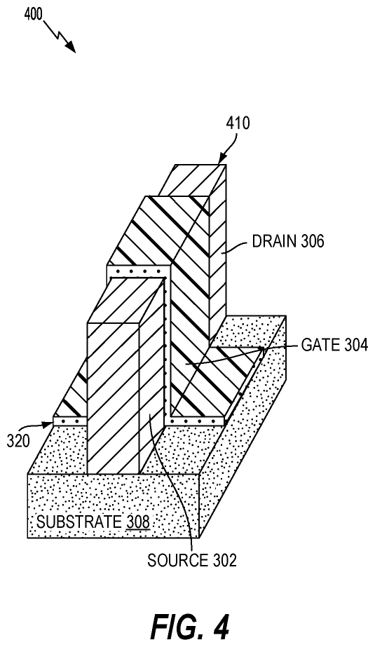

FIG. 4 illustrates a fin-structured FET (FinFET 400) that operates in a similar fashion to the MOSFET device 300 described with respect to FIG. 3. According to aspects of the present disclosure, the FinFET 400 may include multiple gate spacers. A fin 410 in a FinFET 400, however, is grown or otherwise coupled to the substrate 308. The substrate 308 may be a semiconductor substrate or other like supporting layer, for example, comprised of an oxide layer, a nitride layer, a metal oxide layer, or a silicon layer. The fin 410 includes the source 302 and the drain 306. The gate 304 is disposed on the fin 410 and on the substrate 308 through the gate insulator 320. A FinFET transistor is a 3D fin-based metal-oxide-semiconductor field-effect transistor (MOSFET). As a result, the physical size of the FinFET 400 may be smaller than the MOSFET device 300 structure shown in FIG. 3. This reduction in physical size allows for more devices per unit area on the die 106.

The fabrication of integrated circuits is a complex process that may involve hundreds of individual operations. The process includes the diffusion of precisely predetermined amounts of dopant material into portions of a silicon wafer to produce active regions for producing junctions to be used in devices, such as transistors. In exemplary current processes, there may be multiple (e.g., ten) interconnect layers (“metal layers”) with a conductive (polysilicon (“poly”) or metal gate) gate line over an active region of a transistor. Features at layers connecting one interconnect layer to another interconnect layer (either above or below a given layer) are called vias. Features at layers connecting one interconnect layer to semiconductor active regions are called contacts (e.g., conductive contacts characteristic of the test structure).

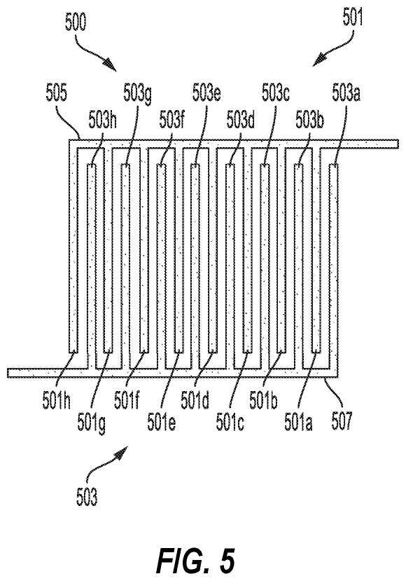

In order to detect defects that arise during fabrication of integrated circuits, test structures may be formed upon designated sites on a semiconductor wafer. Formation of the test structures may include multiple processing steps different from processes used to form production integrated circuits. Proper functioning of the layers of an integrated circuit is measured with test structures such as the test structure illustrated in FIG. 5.

FIG. 5 illustrates a double comb test structure 500 having a double comb structure. The double comb test structure 500 serves to detect unwanted short circuits in the integrated circuit. The double comb test structure 500 includes two isolated conductive combs (e.g., a first conductive comb 501 and a second conductive comb 503) with interdigitated branches. For example, the first conductive comb 501 includes a first set of conductive branches 501a-501h orthogonally coupled to a first conductive terminal 505. The second conductive comb 503 includes a second set of conductive branches 503a-503h orthogonally coupled to a second conductive terminal 507. The first set of conductive branches 501a-501h is interdigitated with the second set of conductive branches 503a-503h.

The first conductive comb 501 and the second conductive comb 503 are situated over various wafer terrains to ensure that residual traces of unwanted metal do not exist. The wafer terrains include metal and polysilicon interconnects that are used to form the transistors and their corresponding connections. For example, to test the double comb test structure 500, a voltage or current is applied to the first conductive terminal 505 and current or voltage is sensed at the second conductive terminal 507. A significant current or voltage above a noise floor indicates a short between the first conductive comb 501 and the second conductive comb 503.

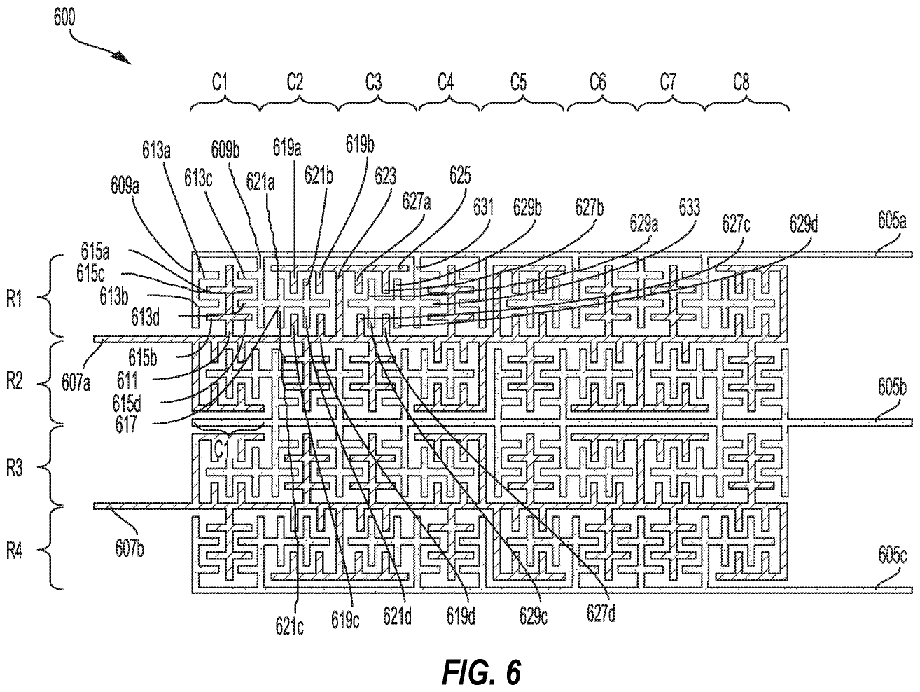

FIG. 6 illustrates a dendritic integrated circuit test structure 600, according to aspects of the present disclosure. The dendritic integrated circuit test structure 600 includes unit cells in conductive layers. The dendritic integrated circuit test structure 600 is situated over various wafer terrains to ensure that residual traces of unwanted metal do not exist. The wafer terrains include metal and gate interconnects that form the transistors and their corresponding connections.

The unit cells are within multiple rows and multiple columns including row one (R1), row two (R2), row three (R3), and row four (R4) as well as column one (C1), column two (C2), column three (C3), column four (C4), column five (C5), column six (C6), column seven (C7), and column eight (C8). In the interest of brevity, a description of the aspects of the disclosure are directed to a few of the unit cells. For example, the dendritic integrated circuit test structure 600 includes a first unit cell in row one (R1) column one (C1), a second unit cell in row one (R1) column two (C2), and a third unit cell in row one (R1) column three (C3).

The unit cells include a first set of trunks and a first set of branches coupled to a first set of conductive terminals, and a second set of trunks and a second set of branches coupled to a second set of conductive terminals. The test-structure detect shorts for every specific conductive layer without necessarily being connected to the transistors. In the absence of a latent defect, the first set of conductive terminals and its corresponding first set of trunks and first set of branches are electrically independent of the second set of conductive terminals and its corresponding second set of trunks and second set of branches. However, in the presence of a latent defect, the branches or the trunks associated with the first set of conductive terminals may be shorted with the branches or the trunks associated with the second set of conductive terminals. To test the dendritic integrated circuit test structure 600, a voltage or current is applied to the first set of conductive terminals and current or voltage is sensed at the second set of conductive terminals. A significant current or voltage above a noise floor indicates a short between the first set of conductive terminals and the second set of conductive terminals.

For example, the first set of conductive terminals includes a first conductive terminal 605a, a second conductive terminal 605b, and a third conductive terminal 605c. The second set of conductive terminals includes a fourth conductive terminal 607a and a fifth conductive terminal 607b. To detect a latent defect, a charge (e.g., current or voltage) of a first polarity is applied to the first conductive terminal 605a, the second conductive terminal 605b, and the third conductive terminal 605c as well as their corresponding branches and trunks. Another charge of a second polarity is applied to the fourth conductive terminal 607a and the fifth conductive terminal 607b as well as their corresponding branches and trunks. Thus, the first set of conductive terminals and corresponding trunks and branches are of a first polarity and the second set of conductive terminals and corresponding trunks and branches are of a second polarity. The first polarity (e.g., positive) is different from the second polarity (e.g., negative or ground). A significant current or voltage above some noise floor indicates a short between the first set of conductive terminals and the second set of conductive terminals.

In one aspect of the disclosure, the dendritic integrated circuit test structure 600 includes a first set of unit cells in a first conductive layer. For example, the first set of unit cells includes the first unit cell in row one (R1) column one (C1). The dendritic integrated circuit test structure 600 includes a second set of unit cells in the first conductive layer. For example, the second set of unit cells includes the second unit cell in row one (R1) column two (C2). The second unit cell in row one (R1) column two (C2) is adjacent to the first unit cell in row one (R1) column one (C1). The dendritic integrated circuit test structure 600 includes a third set of unit cells in the first conductive layer. For example, the third set of unit cells includes the third unit cell in row one (R1) column three (C3). The third unit cell in row one (R1) column three (C3) is adjacent to the second unit cell in row one (R1) column two (C2). The dendritic integrated circuit test structure 600 includes a fourth set of unit cells in the first conductive layer. For example, the fourth set of unit cells includes the fifth unit cell in row two (R2) column one (C1). The fifth unit cell in row two (R2) column one (C1) is adjacent to the first unit cell in row one (R1) column one (C1). The subsequent unit cells are either rotated or mirrored from the first unit cell.

The first unit cell in row one (R1) column one (C1) of the first set of unit cells includes a first portion to receive the charge of a first polarity and a second portion to receive the charge of the second polarity. The first portion has a first trunk 609a and a second trunk 609b parallel to the first trunk 609a. The first trunk 609a and the second trunk 609b are orthogonally coupled to the first conductive terminal 605a. The second portion also has a third trunk 611 between the first trunk 609a and the second trunk 609b. The third trunk 611 is parallel to the first trunk 609a and the second trunk 609b. The third trunk 611 is orthogonally coupled to the fourth conductive terminal 607a.

The first portion also has a first set of branched conductive lines orthogonally coupled to the first trunk 609a and the second trunk 609b. The second portion has a second set of branched conductive lines orthogonally coupled to the third trunk 611. The first set of branched conductive lines of the first portion are interdigitated with the second set of branched conductive lines of the second portion. For example, the first set of branched conductive lines includes a first branched conductive line 613a and a second branched conductive line 613b orthogonally coupled to the first trunk 609a (e.g., a conductive trunk). The first set of branched conductive lines also includes a third branched conductive line 613c and a fourth branched conductive line 613d orthogonally coupled to the second trunk 609b.

The second set of branched conductive lines includes a fifth branched conductive line 615a, a sixth branched conductive line 615b, a seventh branched conductive line 615c and an eighth branched conductive line 615d all orthogonally coupled to the third trunk 611. The first branched conductive line 613a and the second branched conductive line 613b are interdigitated with the fifth branched conductive line 615a and the sixth branched conductive line 615b. The third branched conductive line 613c and the fourth branched conductive line 613d are interdigitated with the seventh branched conductive line 615c and the eighth branched conductive line 615d.

In one aspect of the disclosure, the second set of unit cells is transposed (e.g., rotated/mirrored) relative to the first set of unit cells. For example, the second unit cell in row one (R1) column two (C2) is rotated relative to the first unit cell in row one (R1) column one (C1). The second unit cell in row one (R1) column two (C2) may be rotated ninety degrees relative to the first unit cell in row one (R1) column one (C1) and the terminal connections swapped such that the polarity of charge to rotated portions are swapped. We note that the transposition of the unit cells may be different or changed to for a different unit cell. For example, one unit cell may be transposed in one way while other unit another unit cell is transposed in another way in accordance with different configurations or patterns.

For example, the second unit cell in row one (R1) column two (C2) includes a fourth trunk 617, which corresponds to the third trunk 611 rotated by ninety degrees with a swapped polarity. The fourth trunk 617 is orthogonally coupled to the second trunk 609b. The fourth trunk 617 has branched conductive lines 621a, 621b, 621c, and 621d, which correspond to the fifth branched conductive line 615a, the sixth branched conductive line 615b, the seventh branched conductive line 615c, and the eighth branched conductive line 615d that are rotated by ninety degrees and have a swapped polarity.

Branched conductive lines 619a and 619b are orthogonally coupled to a trunk 625 while branched conductive lines 619c and 619d are orthogonally coupled to the fourth conductive terminal 607a. The branched conductive lines 619a, 619b, 619c, and 619d correspond to the first branched conductive line 613a, the second branched conductive line 613b, the third branched conductive line 613c, and the fourth branched conductive line 613d that are rotated by ninety degrees and have a polarity that is swapped.

The third set of unit cells is transposed (e.g., rotated/mirrored) relative to the second set of unit cells. For example, the third unit cell in row one (R1) column three (C3) is a mirror image of the second unit cell in row one (R1) column two (C2). The mirror image occurs along an axis corresponding to a branched conductive line 623 shared by the second unit cell in row one (R1) column two (C2) and the third unit cell in row one (R1) column three (C3). For example, branched conductive lines 627a, 627b, 627c, and 627d of the third unit cell that are orthogonally coupled to the trunk 625 or the fourth conductive terminal 607a are a mirror image of the branched conductive lines 619a, 619b, 619c, and 619d of the second unit cell. Similarly, branched conductive lines 629a, 629b, 629c, and 629d of the third unit cell that are orthogonally coupled to a trunk 633 are a mirror image of branched conductive lines 621a, 621b, 621c, and 621d of the second unit cell. The trunk 633 is orthogonally coupled to another trunk 631. In the mirror configuration, the polarity of the trunks and the branched conductive lines remain the same for both mirror images.

Although the description is directed to a dendritic integrated circuit test structure having conductive elements (e.g., branched conductive lines, branches or sub-branches, trunks and conductive terminals) that are orthogonal relative to each other, the conductive elements can also be in other configurations such as an X-type configuration. For example, the concept can be extended to the X-type configuration by rotating conductive elements by 45 degrees. The dendritic integrated circuit test structure can be extended to all metal layers and design rules.

In some aspects, the dendritic test structure follows a specific pattern. For example, if column one (C1), row one (R1) is unit cell A, then column two (C2), row one (R1) is unit cell B and is the same as column one (C1), row one (R1) rotated by ninety degrees with the polarity swapped. Column three (C3), row one (R1) represents flipping or mirroring on the vertical axis. For example, column three (C3), row one (R1) is a mirror image of the second unit cell in row one (R1) column two (C2) along an axis corresponding to the branched conductive line 623 and represented by B′. Column four (C4), row one (R1) is the same as unit cell A. The first four columns (C1-C4) in row one (R1) are therefore represented as M=ABB′A in terms of unit cells. In this aspect, the next four columns (C5-C8) in row one (R1) are represented as N=B′AAB in terms of unit cells.

In this aspect, the eight columns (C1-C8) in row two (R2) are represented by N*M where * represents mirroring of the unit cells of row one along an axis (e.g., the fourth conductive terminal 607a, which may be a horizontal axis). Additionally, in this aspect, the eight columns (C1-C8) in row three (R3) are represented by R2*, which means that the eight columns (C1-C8) in row three (R3) are a mirror image of the eight columns (C1-C8) in row two (R2) along an axis (e.g., the second conductive terminal 605b, which may be a horizontal axis). The eight columns (C1-C8) in row four (R4) are represented by R1*, which means that the eight columns (C1-C8) in row four (R4) are a mirror image of the eight columns (C1-C8) in row one (R1) along an axis (e.g., the fifth conductive terminal 607b, which may be an horizontal axis.) The pattern, as illustrated in FIG. 6, can be repeated as space allows.

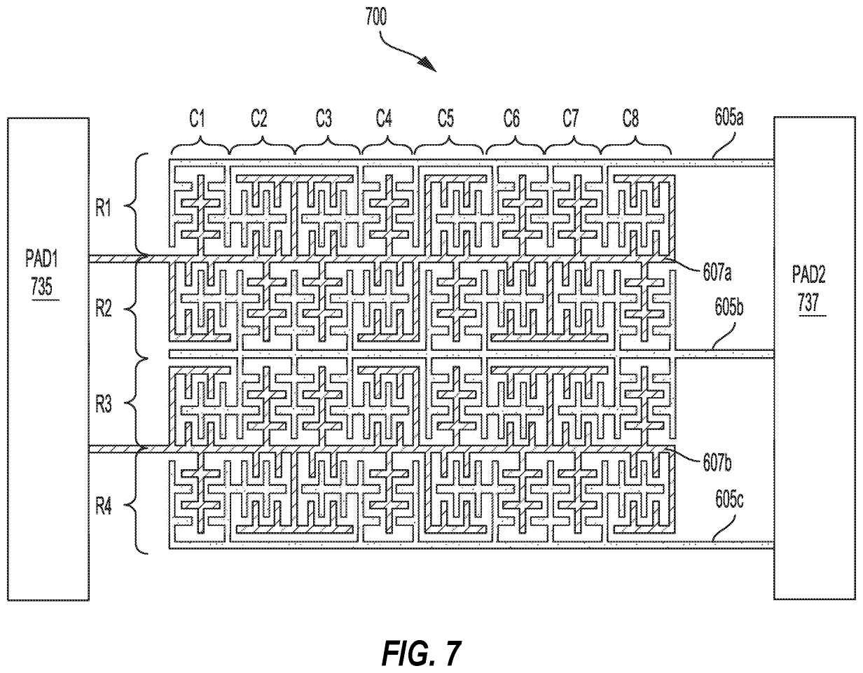

FIG. 7 illustrates a dendritic integrated circuit test structure 700, according to aspects of the present disclosure. For illustrative purposes, some of the labelling and numbering of the devices and features of FIG. 7 are similar to those of FIG. 6. The dendritic integrated circuit test structure 700 includes a first contact pad 735 in the first conductive (e.g., metal) layer and a second contact pad 737 in the first conductive layer. The first contact pad 735 is coupled to the fourth conductive terminal 607a and the fifth conductive terminal 607b. The second contact pad 737 is coupled to the first conductive terminal 605a, the second conductive terminal 605b, and the third conductive terminal 605c.

To detect a latent defect, a charge (e.g., current or voltage) of the first polarity is applied to the first conductive terminal 605a, the second conductive terminal 605b, and the third conductive terminal 605c as well as their corresponding branches and trunks. The charge of the first polarity is applied through the second contact pad 737. Another charge of the second polarity is applied to the fourth conductive terminal 607a and the fifth conductive terminal 607b as well as their corresponding branches and trunks in order to detect any latent defects. The charge of the second polarity is applied through the first contact pad 735. Although the dendritic integrated circuit test structure 700 or 600, the first contact pad 735, and the second contact pad 737 are described as being in the first conductive layer, they can also be implemented in one or more layers. For example, the first contact pad 735 and the second contact pad 737 are in the same conductive layer. The first contact pad 735 and the second contact pad 737 may be used for probing.

In one aspect of the disclosure, an aspect ratio, which corresponds to a ratio of a trunk length to a length of a branch in a unit cell is generally less than three to one (3:1) to ensure coverage in both dimensions and to accelerate detection of failure.

The integrated circuit test structure can be implemented either on a product chip or on a test chip. The integrated circuit test structure can be used in multiple phases of product life. For example, the integrated circuit test structure can be used in an initial BEOL technology “bring-up” during metal process integration (e.g., during photoresist masking, etching, deposition, and CMP steps). The integrated circuit test structure can also be used during a latent defect screen at wafer-level electrical probe, using either regular test or temperature/voltage stress testing. The goal for this use is to isolate portions of the chip that are failing even if the chip is passing regular product probe (Bin1) due to latent defects.

The dendritic integrated circuit test structure is bi-dimensional and dense (with respect to trunks, branches, and sub-branches) in both directions and maximizes or improves perimeter coverage between adjacent metals in order to expedite the detection of metal-to-metal shorts related to latent defects. Further, transposing (e.g., rotating or mirroring) a smallest building block (e.g., a unit cell) of the dendritic integrated circuit test structure allows for both dimensions to be covered equally, which is not the case with conventional comb/meander structures where a metal perimeter is usually longer in one dimension than the other.

The dendritic integrated circuit test structure may incorporate both design rules and sub-design rule spacing structure to achieve the desired density. As a result, failure detection due to metal-to-metal shorts induced by latent defects is accelerated. Thus, when a latent defect is present, this dendritic integrated circuit test structure enables faster detection either at time-zero (T0) screening or at shorter burn-in stress durations, which saves significant test resources and expense.

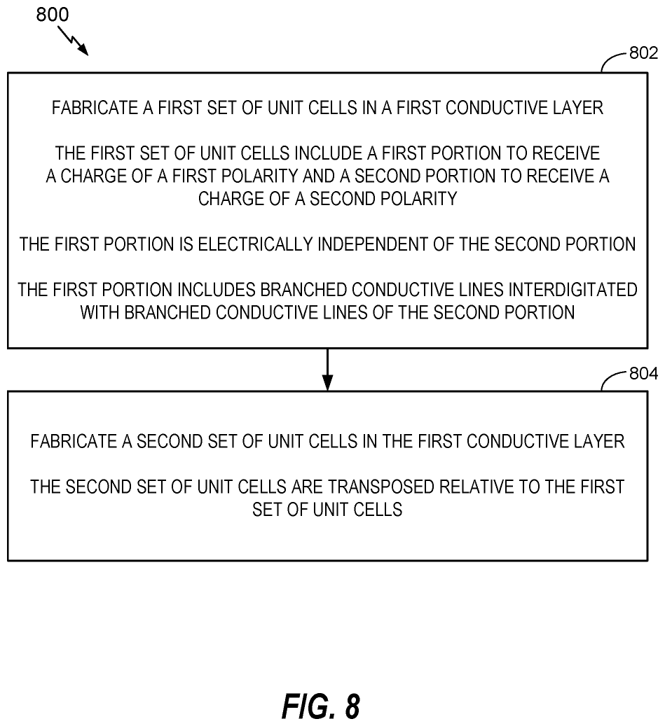

FIG. 8 illustrates a method 800 for fabricating an integrated circuit test structure, according to aspects of the present disclosure. The method 800 begins at block 802, where a first set of unit cells is fabricated in a first conductive layer. The first set of unit cells include a first portion to receive a charge of a first polarity and a second portion to receive a charge of a second polarity. The first portion is electrically independent of the second portion. The first portion includes branched conductive lines interdigitated with branched conductive lines of the second portion. At block 804 a second set of unit cells is fabricated in the first conductive layer and transposed relative to the first set of unit cells.

According to an aspect of the present disclosure, an integrated circuit test structure is described. In one configuration, the integrated circuit test structure includes means for detecting latent defect in the first conductive layer. The latent defect detecting means is transposed relative to the first plurality of unit cells. The latent defect detecting means may be the unit cells in row two (R2) and/or the unit cells in row three (R3). In another aspect, the aforementioned means may be any module or any apparatus or material configured to perform the functions recited by the aforementioned means.

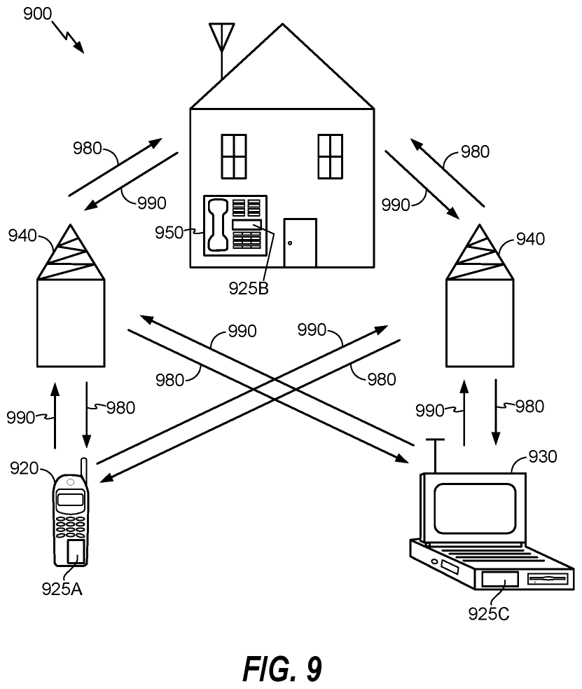

FIG. 9 is a block diagram showing an exemplary wireless communication system in which an integrated circuit test structure of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925C, and 925B that include the disclosed integrated circuit test structure. It will be recognized that other devices may also include the disclosed integrated circuit test structure, such as the base stations, switching devices, and network equipment. FIG. 9 shows forward link signals 980 from the base station 940 to the remote units 920, 930, and 950 and reverse link signals 990 from the remote units 920, 930, and 950 to base station 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit such as a personal data assistant, a GPS enabled devices, a navigation device, a set top box, a music player, a video player, an entertainment unit, a fixed location data unit such as meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed integrated circuit test structure.

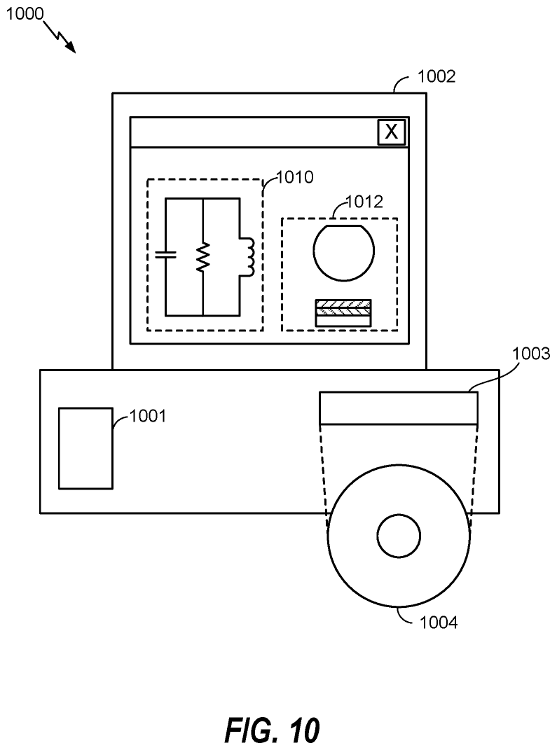

FIG. 10 is a block diagram illustrating a design workstation used for circuit, layout, and logic design of an IC structure, such as the integrated circuit test structure with multiple spacers. A design workstation 1000 includes a hard disk 1001 containing operating system software, support files, and design software such as Cadence or OrCAD. The design workstation 1000 also includes a display 1002 to facilitate design of a circuit 1010 or an IC device 1012 including a novel integrated circuit test structure. A storage medium 1004 is provided for tangibly storing the design of the circuit 1010 or the IC device 1012 including the integrated circuit test structure. The design of the circuit 1010 or the IC device 1012 including the integrated circuit test structure may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the IC device 1012 by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit test structure, comprising:
a first plurality of unit cells in a first conductive layer, the first plurality of unit cells comprising a first portion to receive a charge of a first polarity and a second portion to receive a charge of a second polarity, the first portion electrically independent of the second portion, the first portion comprising branched conductive lines interdigitated with branched conductive lines of the second portion; and
a second plurality of unit cells in the first conductive layer, the second plurality of unit cells transposed relative to the first plurality of unit cells.

2. The integrated circuit test structure of claim 1, further comprising:
a first contact pad of the first polarity in the first conductive layer, the first contact pad coupled to the first portion of the first plurality of unit cells; and
a second contact pad of the second polarity in the first conductive layer, the second contact pad coupled to the second portion of the first plurality of unit cells.

3. The integrated circuit test structure of claim 1, in which the second plurality of unit cells are rotated relative to the first plurality of unit cells.

4. The integrated circuit test structure of claim 3, in which an angle of rotation is ninety degrees.

5. The integrated circuit test structure of claim 3, in which the first polarity and the second polarity of the second plurality of unit cells are swapped relative to the first polarity and the second polarity of the first plurality of unit cells.

6. The integrated circuit test structure of claim 3, in which the branched conductive lines of the second plurality of unit cells are rotated relative to the branched conductive lines of the first plurality of unit cells.

7. The integrated circuit test structure of claim 1, in which the second plurality of unit cells is a mirror image of the first plurality of unit cells.

8. The integrated circuit test structure of claim 7, in which the first polarity and the second polarity of the second plurality of unit cells are maintained relative to the first polarity and the second polarity of the first plurality of unit cells.

9. The integrated circuit test structure of claim 7, in which the branched conductive lines are coupled to a plurality of conductive trunks, an aspect ratio of a trunk length to a length of a branched conductive line is less than three to one (3:1).

10. A method of fabricating an integrated circuit test structure comprising:
fabricating a first plurality of unit cells in a first conductive layer, the first plurality of unit cells comprising a first portion to receive a charge of a first polarity and a second portion to receive a charge of a second polarity, the first portion electrically independent of the second portion, the first portion comprising branched conductive lines interdigitated with branched conductive lines of the second portion; and
fabricating a second plurality of unit cells in the first conductive layer, the second plurality of unit cells transposed relative to the first plurality of unit cells.

11. The method of claim 10, further comprising:
fabricating a first contact pad of the first polarity in the first conductive layer, the first contact pad coupled to the first portion of the plurality of unit cells; and
fabricating a second contact pad of the second polarity in the first conductive layer, the second contact pad coupled to the second portion of the plurality of unit cells.

12. The method of claim 10, further comprising rotating the second plurality of unit cells relative to the first plurality of unit cells.

13. The method of claim 12, further comprising swapping the first polarity and the second polarity of the second plurality of unit cells relative to the first polarity and the second polarity of the first plurality of unit cells.

14. The method of claim 12, further comprising rotating the branched conductive lines of the second plurality of unit cells relative to the branched conductive lines of the first plurality of unit cells.

15. An integrated circuit test structure, comprising:
a first plurality of unit cells in a first conductive layer, the first plurality of unit cells comprising a first portion to receive a charge of a first polarity and a second portion to receive a charge of a second polarity, the first portion electrically independent of the second portion, the first portion comprising branched conductive lines interdigitated with branched conductive lines of the second portion; and
means for detecting latent defect in the first conductive layer, the latent defect detecting means transposed relative to the first plurality of unit cells.

16. The integrated circuit test structure of claim 15, further comprising:
a first contact pad of the first polarity in the first conductive layer, the first contact pad coupled to the first portion of the first plurality of unit cells; and
a second contact pad of the second polarity in the first conductive layer, the second contact pad coupled to the second portion of the first plurality of unit cells.

17. The integrated circuit test structure of claim 15, in which the latent defect detecting means are rotated relative to the first plurality of unit cells.

18. The integrated circuit test structure of claim 17, in which an angle of rotation is ninety degrees.

19. The integrated circuit test structure of claim 17, in which the first polarity and the second polarity of the latent defect detecting means are swapped relative to the first polarity and the second polarity of the first plurality of unit cells.

20. The integrated circuit test structure of claim 17, in which the branched conductive lines of the latent defect detecting means are rotated relative to the branched conductive lines of the first plurality of unit cells.
